(19) United States
(12) Patent Application Publication
(10) Pub. No.: US 2007/0173167 A1
(43) Pub. Date: Jul. 26, 2007

(54) Organic light-emitting display device and method of fabricating the same

(76) Inventor: Young Seo Choi, Yongin-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/541,055

(22) Filed: Sep. 29, 2006

(30) Foreign Application Priority Data
Jan. 26, 2006 (KR) 10-2006-0008464

(51) Int. Cl. H05B 33/10; H01L 51/56

(52) U.S. Cl. 445/25; 445/24

(57) ABSTRACT

Disclosed is a method for preparing an organic light-emitting display device in which a substrate and an encapsulation substrate are completely coalesced using a frit. The method for preparing an organic light-emitting display device according to one aspect of the present invention includes a first substrate including an organic light-emitting diode and a second substrate for encapsulating at least a pixel region of the first substrate, the method including applying a first frit paste to surround the pixel region in the first substrate, and applying a second frit paste to be faced against the first frit paste in the second substrate, sintering the first and the second frit pastes to form a first frit and a second frit, respectively, coalescing the first substrate to the second substrate to contact the first frit and the second frit to each other, attaching the first substrate and the second substrate to each other by irradiating a laser or an infrared ray to the first frit and the second frit, both contacted to each other.

### CROSS-REFERENCE TO RELATED APPLICATIONS

This application claims the benefit of Korean Patent Application No. 2006-8464, filed on Jan. 26, 2006, in the Korean Intellectual Property Office, the disclosure of which is incorporated herein by reference. This application is related to and incorporates herein by reference the entire contents of the following concurrently filed applications:

| | | | Application |
|---|---|---|---|
| Title | Atty. Docket No. | Filing Date | No. |
| ORGANIC LIGHT-EMITTING DISPLAY | SDISHN.045AUS | | |
| DEVICE AND METHOD OF | | | |
| MANUFACTURING THE SAME | | | |
| ORGANIC LIGHT EMITTING DISPLAY | SDISHN.048AUS | | |
| DEVICE | | | |
| ORGANIC LIGHT-EMITTING DISPLAY | SDISHN.051AUS | | |
| DEVICE WITH FRIT SEAL AND | | | |
| REINFORCING STRUCTURE | | | |
| ORGANIC LIGHT EMITTING DISPLAY | SDISHN.052AUS | | |
| DEVICE METHOD OF FABRICATING | | | |
| THE SAME | | | |
| ORGANIC LIGHT EMITTING DISPLAY | SDISHN.053AUS | | |
| AND METHOD OF FABRICATING THE | | | |
| SAME | | | |
| ORGANIC LIGHT-EMITTING DISPLAY | SDISHN.054AUS | | |
| DEVICE WITH FRIT SEAL AND | | | |
| REINFORCING STRUCTURE BONDED | | | |
| TO FRAME | | | |
| METHOD FOR PACKAGING ORGANIC | SDISHN.055AUS | | |
| LIGHT EMITTING DISPLAY WITH | | | |
| FRIT SEAL AND REINFORCING | | | |
| STURUTURE | | | |
| METHOD FOR PACKAGING ORGANIC | SDISHN.056AUS | | |
| LIGHT EMITTING DISPLAY WITH | | | |
| FRIT SEAL AND REINFORCING | | | |
| STURUTURE | | | |
| ORGANIC LIGHT-EMITTING DISPLAY | SDISHN.060AUS | | |
| DEVICE AND THE PREPARATION | | | |
| METHOD OF THE SAME | | | |
| ORGANIC LIGHT EMITTING DISPLAY | SDISHN.061AUS | | |
| AND FABRICATING METHOD OF THE | | | |
| SAME | | | |
| ORGANIC LIGHT-EMITTING DISPLAY | SDISHN.062AUS | | |
| AND METHOD OF MAKING THE | | | |
| SAME | | | |
| ORGANIC LIGHT EMITTING DISPLAY | SDISHN.063AUS | | |
| AND FABRICATING METHOD OF THE | | | |
| SAME | | | |
| ORGANIC LIGHT EMITTING DISPLAY | SDISHN.064AUS | | |
| DEVICE AND MANUFACTURING | | | |
| METHOD THEREOF | | | |
| ORGANIC LIGHT-EMITTING DISPLAY | SDISHN.066AUS | | |
| DEVICE AND MANUFACTURING | | | |
| METHOD OF THE SAME | | | |
| ORGANIC LIGHT EMITTING DISPLAY | SDISHN.067AUS | | |
| AND FABRICATING METHOD OF THE | | | |
| SAME | | | |
| ORGANIC LIGHT EMITTING DISPLAY | SDISW.017AUS | | |
| AND METHOD OF FABRICATING THE | | | |
| SAME | | | |
| ORGANIC LIGHT EMITTING DISPLAY | SDISW.018AUS | | |
| DEVICE METHOD OF FABRICATING | | | |
| THE SAME | | | |
| ORGANIC LIGHT EMITTING DISPLAY | SDISW.020AUS | | |
| AND METHOD OF FABRICATING THE | | | |
| SAME | | | |

### BACKGROUND OF THE INVENTION

1. Field of the Invention

The present invention relates to organic light-emitting display devices. More particularly, the present invention relates to packaging of organic light-emitting display devices.

2. Description of the Related Art

Generally, an organic light-emitting display device is a flat panel display in which an electron injected to one electrode and a hole injected to the other electrode bind to each other in an organic light-emitting layer. If the organic light-emitting layer is arranged between facing electrodes and a voltage is applied to both electrodes, and if luminescent molecules of the light-emitting layer are excited by the electron binding to the hole, then an energy is emitted by returning to a ground state and the energy is then converted into the light.

Organic light-emitting display devices exhibiting such a light-emission principle have drawn attention as a next-generation display since they are excellent in visibility, and they may be also manufactured in a light weight and thin shape and driven at a low voltage.

One of the problems associated with the organic light-emitting display device is that the organic light-emitting diode is deteriorated when moisture is infiltrated into the organic materials constituting the organic light-emitting diode.

U.S. Pat. No. 6,998,776 discloses an organic light-emitting diode that is sealed by coating a glass substrate with a frit and curing the frit without possessing a moisture-absorbing material. According to the patent, a frit is applied to an encapsulation substrate and sintered, and a substrate and the encapsulation substrate are then coalesced to each other, and then the frit is cured using a laser to completely seal a gap between the substrate and the encapsulation substrate.

That is, if the substrate and the encapsulation substrate are sealed using a frit, then there has been adopted a method in which a frit is formed in a side of the encapsulation substrate and thermally sintered, and then the substrate and an encapsulation substrate are attached to each other since the substrate in which an organic light-emitting diode is formed cannot be thermally sintered. In this case, the frit formed in the encapsulation substrate, however, has an excellent adhesive force to the encapsulation substrate, but it has a problem in that the organic light-emitting diode is damaged if its adhesion to the substrate is deteriorated due to a poor adhesive force to the substrate. Thus, improved methods of encapsulating organic light-emitting display devices to protect against degradation due to moisture, oxygen, hydrogen and other substances are needed.

The discussion of this section is to provide a general background of organic light-emitting devices and does not constitute an admission of prior art.

### SUMMARY OF CERTAIN INVENTIVE ASPECTS

An aspect of the invention provides an organic light-emitting display device. This device includes a first substrate, an array of organic light emitting pixels formed on the first substrate, and a second substrate placed over the first substrate, the array being interposed between the first and second substrates. This device also includes a frit seal surrounding the array while interposed between and interconnecting the first substrate and the second substrate; wherein the frit seal comprises a first end connected to the first substrate and a second end connected to the second substrate, wherein the frit seal further comprises a middle portion located between the first and second end, and wherein the frit seal further comprises a trace of bonding in the middle portion.

In the above described device, the trace of bonding may comprise a trace of melting and resolidifying a material of the frit seal. The trace of bonding may be found on a surface of the frit seal. For example, the frit seal may include a slight step, groove or bump on an interior or exterior surface of the frit seal. The trace of bonding may be substantially planar. The trace of bonding may be substantially parallel to a surface of the first and second substrates. The trace of bonding may comprises a three-dimensional geography. The frit seal may be substantially free of bubbles along the trace of bonding. The frit seal may comprise air bubbles in the vicinity of the trace of bonding. The frit seal may comprise a first tapered portion slightly tapered in a direction from the first substrate toward the trace of bonding, and wherein the frit seal further comprises a second tapered portion slightly tapered in a direction from the second substrate toward the trace of bonding. In this case, the first tapered portion and the second tapered portion may meet at the trace of bonding.

Another aspect of the invention provides a method of manufacturing an organic light-emitting display device. This method includes providing a first unfinished product comprising a first substrate and an array of organic light-emitting pixels formed over the first substrate, the first unfinished product further comprising a first frit structure formed over the first substrate and surrounding the array, the first frit structure comprising a first surface generally facing away from the first substrate. This method further includes providing a second unfinished product comprising a second substrate and a second frit structure formed over the second substrate, the second frit structure comprising a second surface generally facing away from the second substrate. The method further includes arranging the first and second unfinished products such that the first and second surfaces face and contact each other and melting and solidifying at least part of the first and second frit structures where the first and second frit structures contact so as to bond the first and second frit structures together, thereby forming an integrated frit seal interposed between the first and second substrate.

In the above described method, the first frit structure may form a closed loop surrounding the array, and the second frit structure may form a corresponding closed loop over the second substrate. The first and second surfaces may be shaped complementary so as to substantially fit with each other when the first and second unfinished products are arranged. The integrated frit may be substantially free of bubbles along where the first and second surfaces contact. Providing the first unfinished product may further comprise providing the first substrate and the array formed over the first substrate, forming a structure with a frit material, and at least partially curing the structure of the frit material, thereby forming the first frit structure.

Still referring to the above described method, the first unfinished product may further comprise a plurality of additional arrays of organic light emitting pixels formed over the first substrate and a plurality of additional frit structures formed over the first substrate, each additional frit structure comprising a surface facing away from the first substrate. The second unfinished product further comprises a plurality of additional frit structures formed over the second substrate, each additional frit structure of the second unfinished product comprising a surface facing away from the second substrate. Upon arranging the first and second unfinished products, the surface of one of the additional frit structures of the first unfinished product contacts the surface of one of the additional frit structures of the second unfinished product, and the method further comprises melting and solidifying at least part of the two additional frit structures where the two additional frit structures contact so as to bond the two additional frit structures together, thereby forming an additional integrated frit seal interposed between the first and second substrate. Each of the additional integrated frit seals may surround one of the additional arrays. The method may further comprise cutting the resulting product into two or more pieces, wherein one of the pieces comprises the integrated frit and the array interposed between the first and second substrate.

An aspect of the invention provides a method of preparing an organic light-emitting display device including a first substrate containing an organic light-emitting diode, and a second substrate for encapsulating at least a pixel region of the first substrate. The method includes applying a first frit paste to surround a pixel region in the first substrate, and applying a second frit paste to the second substrate. The method further includes sintering the first and the second frit pastes to form a first frit and a second frit, respectively, coalescing the first substrate to the second substrate to contact the first frit and the second frit to each other, and bonding the first substrate and the second substrate to each other by irradiating with a laser beam or an infrared ray to the first frit and the second frit, both contacted to each other.

### BRIEF DESCRIPTION OF THE DRAWINGS

These and/or other aspects and advantages of the invention will become apparent and more readily appreciated from the following description of the preferred embodiments, taken in conjunction with the accompanying drawings of which:

FIG. 1 is a cross-sectional view showing an organic light-emitting display device according to an embodiment;

FIG. 2 is a plane view showing an organic light-emitting display device according to an embodiment;

FIG. 3 is a cross-sectional view showing an organic light-emitting display device according to the embodiment of FIG. 2;

FIGS. 4a to 4d are cross-sectional views showing a process for preparing an organic light-emitting display device according to an embodiment;

FIGS. 5a to 5c are cross-sectional views showing other embodiments of frit structures that can be formed in the process shown in FIGS. 4a to 4d;

FIG. 6A is a schematic exploded view of a passive matrix type organic light emitting display device in accordance with one embodiment.

FIG. 6B is a schematic exploded view of an active matrix type organic light emitting display device in accordance with one embodiment.

FIG. 6C is a schematic top plan view of an organic light emitting display in accordance with one embodiment.

FIG. 6D is a cross-sectional view of the organic light emitting display of FIG. 6C, taken along the line d-d.

FIG. 6E is a schematic perspective view illustrating mass production of organic light emitting devices in accordance with one embodiment.

### DETAILED DESCRIPTION OF CERTAIN INVENTIVE EMBODIMENTS

Hereinafter, preferred embodiments of the present invention will be described in detail with reference to the accompanying drawings.

An organic light emitting display (OLED) is a display device comprising an array of organic light emitting diodes. Organic light emitting diodes are solid state devices which include an organic material and are adapted to generate and emit light when appropriate electrical potentials are applied.

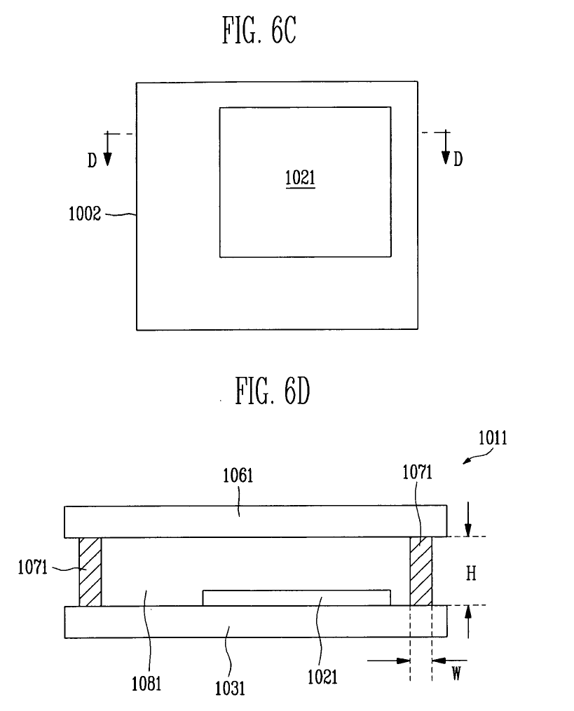

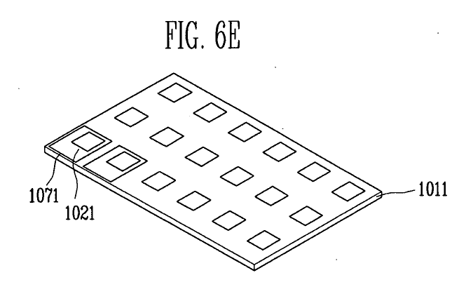

OLEDs can be generally grouped into two basic types dependent on the arrangement with which the stimulating electrical current is provided. FIG. 6A schematically illustrates an exploded view of a simplified structure of a passive matrix type OLED 1000. FIG. 6B schematically illustrates a simplified structure of an active matrix type OLED 1001. In both configurations, the OLED 1000, 1001 includes OLED pixels built over a substrate 1002, and the OLED pixels include an anode 1004, a cathode 1006 and an organic layer 1010. When an appropriate electrical current is applied to the anode 1004, electric current flows through the pixels and visible light is emitted from the organic layer.

Referring to FIG. 6A, the passive matrix OLED (PMOLED) design includes elongate strips of anode 1004 arranged generally perpendicular to elongate strips of cathode 1006 with organic layers interposed therebetween. The intersections of the strips of cathode 1006 and anode 1004 define individual OLED pixels where light is generated and emitted upon appropriate excitation of the corresponding strips of anode 1004 and cathode 1006. PMOLEDs provide the advantage of relatively simple fabrication.

Referring to FIG. 6B, the active matrix OLED (AMOLED) includes driving circuits 1012 arranged between the substrate 1002 and an array of OLED pixels. An individual pixel of AMOLEDs is defined between the common cathode 1006 and an anode 1004, which is electrically isolated from other anodes. Each local driving circuit 1012 is coupled with an anode 1004 of the OLED pixels and further coupled with a data line 1016 and a scan line 1018. In embodiments, the scan lines 1018 supply select signals that select rows of the driving circuits, and the data lines 1016 supply data signals for particular driving circuits. The data signals and scan signals stimulate the driving circuits 1012, which excite the anodes 1004 so as to emit light from their corresponding pixels.

In the illustrated AMOLED, the local driving circuits 1012, the data lines 1016 and scan lines 1018 are buried in a planarization layer 1014, which is interposed between the pixel array and the substrate 1002. The planarization layer 1014 provides a planar top surface on which the organic light emitting pixel array is formed. The planarization layer 1014 may be formed of organic or inorganic materials, and formed of two or more layers although shown as a single layer. The local driving circuits 1012 are typically formed with thin film transistors (TFT) and arranged in a grid or array under the OLED pixel array. The local driving circuits 1012 may be at least partly made of organic materials, including organic TFT.

AMOLEDs have the advantage of fast response time improving their desirability for use in displaying data signals. Also, AMOLEDs have the advantages of consuming less power than passive matrix OLEDs.

Referring to common features of the PMOLED and AMOLED designs, the substrate 1002 provides structural support for the OLED pixels and circuits. In various embodiments, the substrate 1002 can comprise rigid or flexible materials as well as opaque or transparent materials, such as plastic, glass, and/or foil. As noted above, each OLED pixel or diode is formed with the anode 1004, cathode 1006 and organic layer 1010 interposed therebetween. When an appropriate electrical current is applied to the anode 1004, the cathode 1006 injects electrons and the anode 1004 injects holes. In certain embodiments, the anode 1004 and cathode 1006 are inverted; i.e., the cathode is formed on the substrate 1002 and the anode is opposingly arranged.

Interposed between the cathode 1006 and anode 1004 are one or more organic layers. More specifically, at least one emissive or light emitting layer is interposed between the cathode 1006 and anode 1004. The light emitting layer may comprise one or more light emitting organic compounds. Typically, the light emitting layer is configured to emit visible light in a single color such as blue, green, red or white. In the illustrated embodiment, one organic layer 1010 is formed between the cathode 1006 and anode 1004 and acts as a light emitting layer. Additional layers, which can be formed between the anode 1004 and cathode 1006, can include a hole transporting layer, a hole injection layer, an electron transporting layer and an electron injection layer.

Hole transporting and/or injection layers can be interposed between the light emitting layer 1010 and the anode 1004. Electron transporting and/or injecting layers can be interposed between the cathode 1006 and the light emitting layer 1010. The electron injection layer facilitates injection of electrons from the cathode 1006 toward the light emitting layer 1010 by reducing the work function for injecting electrons from the cathode 1006. Similarly, the hole injection layer facilitates injection of holes from the anode 1004 toward the light emitting layer 1010. The hole and electron transporting layers facilitate movement of the carriers injected from the respective electrodes toward the light emitting layer.

In some embodiments, a single layer may serve both electron injection and transportation functions or both hole injection and transportation functions. In some embodiments, one or more of these layers are lacking. In some embodiments, one or more organic layers are doped with one or more materials that help injection and/or transportation of the carriers. In embodiments where only one organic layer is formed between the cathode and anode, the organic layer may include not only an organic light emitting compound but also certain functional materials that help injection or transportation of carriers within that layer.

There are numerous organic materials that have been developed for use in these layers including the light emitting layer. Also, numerous other organic materials for use in these layers are being developed. In some embodiments, these organic materials may be macromolecules including oligomers and polymers. In some embodiments, the organic materials for these layers may be relatively small molecules. The skilled artisan will be able to select appropriate materials for each of these layers in view of the desired functions of the individual layers and the materials for the neighboring layers in particular designs.

In operation, an electrical circuit provides appropriate potential between the cathode 1006 and anode 1004. This results in an electrical current flowing from the anode 1004 to the cathode 1006 via the interposed organic layer(s). In one embodiment, the cathode 1006 provides electrons to the adjacent organic layer 1010. The anode 1004 injects holes to the organic layer 1010. The holes and electrons recombine in the organic layer 1010 and generate energy particles called “excitons.” The excitons transfer their energy to the organic light emitting material in the organic layer 1010, and the energy is used to emit visible light from the organic light emitting material. The spectral characteristics of light generated and emitted by the OLED 1000, 1001 depend on the nature and composition of organic molecules in the organic layer(s). The composition of the one or more organic layers can be selected to suit the needs of a particular application by one of ordinary skill in the art.

OLED devices can also be categorized based on the direction of the light emission. In one type referred to as “top emission” type, OLED devices emit light and display images through the cathode or top electrode 1006. In these embodiments, the cathode 1006 is made of a material transparent or at least partially transparent with respect to visible light. In certain embodiments, to avoid losing any light that can pass through the anode or bottom electrode 1004, the anode may be made of a material substantially reflective of the visible light. A second type of OLED devices emits light through the anode or bottom electrode 1004 and is called “bottom emission” type. In the bottom emission type OLED devices, the anode 1004 is made of a material which is at least partially transparent with respect to visible light. Often, in bottom emission type OLED devices, the cathode 1006 is made of a material substantially reflective of the visible light. A third type of OLED devices emits light in two directions, e.g. through both anode 1004 and cathode 1006. Depending upon the direction(s) of the light emission, the substrate may be formed of a material which is transparent, opaque or reflective of visible light.

In many embodiments, an OLED pixel array 1021 comprising a plurality of organic light emitting pixels is arranged over a substrate 1002 as shown in FIG. 6C. In embodiments, the pixels in the array 1021 are controlled to be turned on and off by a driving circuit (not shown), and the plurality of the pixels as a whole displays information or image on the array 1021. In certain embodiments, the OLED pixel array 1021 is arranged with respect to other components, such as drive and control electronics to define a display region and a non-display region. In these embodiments, the display region refers to the area of the substrate 1002 where OLED pixel array 1021 is formed. The non-display region refers to the remaining areas of the substrate 1002. In embodiments, the non-display region can contain logic and/or power supply circuitry. It will be understood that there will be at least portions of control/drive circuit elements arranged within the display region. For example, in PMOLEDs, conductive components will extend into the display region to provide appropriate potential to the anode and cathodes. In AMOLEDs, local driving circuits and data/scan lines coupled with the driving circuits will extend into the display region to drive and control the individual pixels of the AMOLEDs.

One design and fabrication consideration in OLED devices is that certain organic material layers of OLED devices can suffer damage or accelerated deterioration from exposure to water, oxygen or other harmful gases. Accordingly, it is generally understood that OLED devices be sealed or encapsulated to inhibit exposure to moisture and oxygen or other harmful gases found in a manufacturing or operational environment. FIG. 6D schematically illustrates a cross-section of an encapsulated OLED device 1011 having a layout of FIG. 6C and taken along the line d-d of FIG. 6C. In this embodiment, a generally planar top plate or substrate 1061 engages with a seal 1071 which further engages with a bottom plate or substrate 1002 to enclose or encapsulate the OLED pixel array 1021. In other embodiments, one or more layers are formed on the top plate 1061 or bottom plate 1002, and the seal 1071 is coupled with the bottom or top substrate 1002, 1061 via such a layer. In the illustrated embodiment, the seal 1071 extends along the periphery of the OLED pixel array 1021 or the bottom or top plate 1002, 1061.

In embodiments, the seal 1071 is made of a frit material as will be further discussed below. In various embodiments, the top and bottom plates 1061, 1002 comprise materials such as plastics, glass and/or metal foils which can provide a barrier to passage of oxygen and/or water to thereby protect the OLED pixel array 1021 from exposure to these substances. In embodiments, at least one of the top plate 1061 and the bottom plate 1002 are formed of a substantially transparent material.

To lengthen the life time of OLED devices 1011, it is generally desired that seal 1071 and the top and bottom plates 1061, 1002 provide a substantially non-permeable seal to oxygen and water vapor and provide a substantially hermetically enclosed space 1081. In certain applications, it is indicated that the seal 1071 of a frit material in combination with the top and bottom plates 1061, 1002 provide a barrier to oxygen of less than approximately 10⁻³ cc/m²-day and to water of less than 10⁻⁶ g/m²-day. Given that some oxygen and moisture can permeate into the enclosed space 1081, in some embodiments, a material that can take up oxygen and/or moisture is formed within the enclosed space 1081.

The seal 1071 has a width W, which is its thickness in a direction parallel to a surface of the top or bottom substrate 1061, 1002 as shown in FIG. 6D. The width varies among embodiments and ranges from about 300 μm to about 3000 μm, optionally from about 500 μm to about 1500 μm. Also, the width may vary at different positions of the seal 1071. In some embodiments, the width of the seal 1071 may be the largest where the seal 1071 contacts one of the bottom and top substrate 1002, 1061 or a layer formed thereon. The width may be the smallest where the seal 1071 contacts the other. The width variation in a single cross-section of the seal 1071 relates to the cross-sectional shape of the seal 1071 and other design parameters.

The seal 1071 has a height H, which is its thickness in a direction perpendicular to a surface of the top or bottom substrate 1061, 1002 as shown in FIG. 6D. The height varies among embodiments and ranges from about 2 μm to about 30 μm, optionally from about 10 μm to about 15 μm. Generally, the height does not significantly vary at different positions of the seal 1071. However, in certain embodiments, the height of the seal 1071 may vary at different positions thereof.

In the illustrated embodiment, the seal 1071 has a generally rectangular cross-section. In other embodiments, however, the seal 1071 can have other various cross-sectional shapes such as a generally square cross-section, a generally trapezoidal cross-section, a cross-section with one or more rounded edges, or other configuration as indicated by the needs of a given application. To improve hermeticity, it is generally desired to increase the interfacial area where the seal 1071 directly contacts the bottom or top substrate 1002, 1061 or a layer formed thereon. In some embodiments, the shape of the seal can be designed such that the interfacial area can be increased.

The seal 1071 can be arranged immediately adjacent the OLED array 1021, and in other embodiments, the seal 1071 is spaced some distance from the OLED array 1021. In certain embodiment, the seal 1071 comprises generally linear segments that are connected together to surround the OLED array 1021. Such linear segments of the seal 1071 can extend, in certain embodiments, generally parallel to respective boundaries of the OLED array 1021. In other embodiment, one or more of the linear segments of the seal 1071 are arranged in a non-parallel relationship with respective boundaries of the OLED array 1021. In yet other embodiments, at least part of the seal 1071 extends between the top plate 1061 and bottom plate 1002 in a curvilinear manner.

As noted above, in certain embodiments, the seal 1071 is formed using a frit material or simply “frit” or glass frit,” which includes fine glass particles. The frit particles includes one or more of magnesium oxide (MgO), calcium oxide (CaO), barium oxide (BaO), lithium oxide (Li2O), sodium oxide (Na2O), potassium oxide (K2O), boron oxide (B2O3), vanadium oxide (V2O5), zinc oxide (ZnO), tellurium oxide (TeO2), aluminum oxide (Al2O3), silicon dioxide (SiO2), lead oxide (PbO), tin oxide (SnO), phosphorous oxide (P2O5), ruthenium oxide (Ru2O), rubidium oxide (Rb2O), rhodium oxide (Rh2O), ferrite oxide (Fe2O3), copper oxide (CuO), titanium oxide (TiO2), tungsten oxide (WO3), bismuth oxide (Bi2O3), antimony oxide (Sb2O3), lead-borate glass, tin-phosphate glass, vanadate glass, and borosilicate, etc. In embodiments, these particles range in size from about 2 μm to about 30 μm, optionally about 5 μm to about 10 μm, although not limited only thereto. The particles can be as large as about the distance between the top and bottom substrates 1061, 1002 or any layers formed on these substrates where the frit seal 1071 contacts.

The frit material used to form the seal 1071 can also include one or more filler or additive materials. The filler or additive materials can be provided to adjust an overall thermal expansion characteristic of the seal 1071 and/or to adjust the absorption characteristics of the seal 1071 for selected frequencies of incident radiant energy. The filler or additive material(s) can also include inversion and/or additive fillers to adjust a coefficient of thermal expansion of the frit. For example, the filler or additive materials can include transition metals, such as chromium (Cr), iron (Fe), manganese (Mn), cobalt (Co), copper (Cu), and/or vanadium. Additional materials for the filler or additives include ZnSiO₄, PbTiO₃, ZrO₂, eucryptite.

In embodiments, a frit material as a dry composition contains glass particles from about 20 to 90 about wt %, and the remaining includes fillers and/or additives. In some embodiments, the frit paste contains about 10-30 wt % organic materials and about 70-90% inorganic materials. In some embodiments, the frit paste contains about 20 wt % organic materials and about 80 wt % inorganic materials. In some embodiments, the organic materials may include about 0-30 wt % binder(s) and about 70-100 wt % solvent(s). In some embodiments, about 10 wt % is binder(s) and about 90 wt % is solvent(s) among the organic materials. In some embodiments, the inorganic materials may include about 0-10 wt % additives, about 20-40 wt % fillers and about 50-80 wt % glass powder. In some embodiments, about 0-5 wt % is additive(s), about 25-30 wt % is filler(s) and about 65-75 wt % is the glass powder among the inorganic materials.

In forming a frit seal, a liquid material is added to the dry frit material to form a frit paste. Any organic or inorganic solvent with or without additives can be used as the liquid material. In embodiments, the solvent includes one or more organic compounds. For example, applicable organic compounds are ethyl cellulose, nitro cellulose, hydroxyl propyl cellulose, butyl carbitol acetate, terpineol, butyl cellusolve, acrylate compounds. Then, the thus formed frit paste can be applied to form a shape of the seal 1071 on the top and/or bottom plate 1061, 1002.

In one exemplary embodiment, a shape of the seal 1071 is initially formed from the frit paste and interposed between the top plate 1061 and the bottom plate 1002. The seal 1071 can in certain embodiments be pre-cured or pre-sintered to one of the top plate and bottom plate 1061, 1002. Following assembly of the top plate 1061 and the bottom plate 1002 with the seal 1071 interposed therebetween, portions of the seal 1071 are selectively heated such that the frit material forming the seal 1071 at least partially melts. The seal 1071 is then allowed to resolidify to form a secure joint between the top plate 1061 and the bottom plate 1002 to thereby inhibit exposure of the enclosed OLED pixel array 1021 to oxygen or water.

In embodiments, the selective heating of the frit seal is carried out by irradiation of light, such as a laser or directed infrared lamp. As previously noted, the frit material forming the seal 1071 can be combined with one or more additives or filler such as species selected for improved absorption of the irradiated light to facilitate heating and melting of the frit material to form the seal 1071.

In some embodiments, OLED devices 1011 are mass produced. In an embodiment illustrated in FIG. 6E, a plurality of separate OLED arrays 1021 is formed on a common bottom substrate 1101. In the illustrated embodiment, each OLED array 1021 is surrounded by a shaped frit to form the seal 1071. In embodiments, common top substrate (not shown) is placed over the common bottom substrate 1101 and the structures formed thereon such that the OLED arrays 1021 and the shaped frit paste are interposed between the common bottom substrate 1101 and the common top substrate. The OLED arrays 1021 are encapsulated and sealed, such as via the previously described enclosure process for a single OLED display device. The resulting product includes a plurality of OLED devices kept together by the common bottom and top substrates. Then, the resulting product is cut into a plurality of pieces, each of which constitutes an OLED device 1011 of FIG. 6D. In certain embodiments, the individual OLED devices 1011 then further undergo additional packaging operations to further improve the sealing formed by the frit seal 1071 and the top and bottom substrates 1061, 1002.

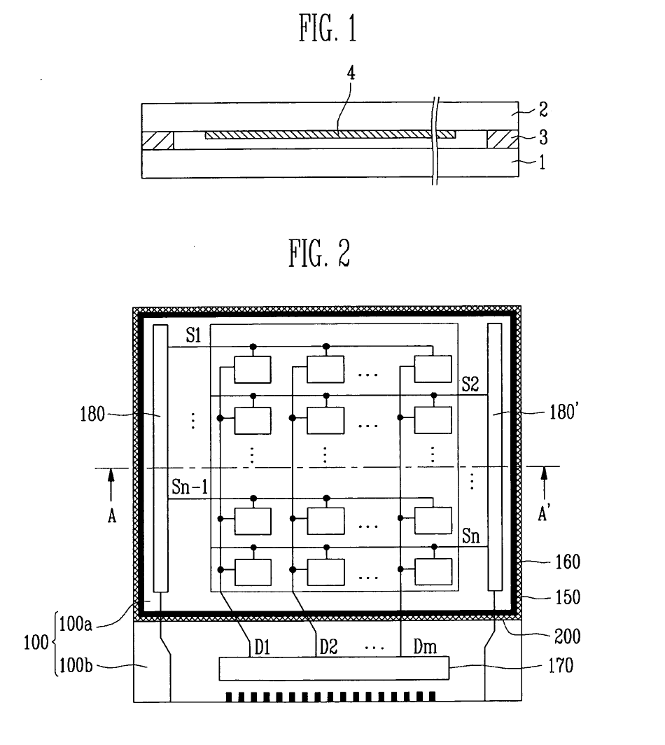

FIG. 1 is a cross-sectional view showing an encapsulation structure of an organic light-emitting diode. The organic light-emitting display device is composed of a deposition substrate 1, an encapsulation substrate 2, a sealing material 3 and a moisture-absorbing material 4. The deposition substrate 1 includes a pixel region including at least one organic light-emitting diode, a non-pixel region surrounding the pixel region, and the encapsulation substrate 2 attached to a surface in which an organic light-emitting diode of the deposition substrate 1 is formed.

In order to attach the deposition substrate 1 to the encapsulation substrate 2, the sealing material 3 is applied along edges of the deposition substrate 1 and the encapsulation substrate 2, and the sealing material 3 is then cured using UV irradiation, etc. The moisture-absorbing material 4 (e.g., a desiccant) is included in the encapsulation substrate 2 for the purpose of removing hydrogen, oxygen, moisture and so on if they infiltrate between fine gaps even though the sealing material 3 is applied.

Even in the case of such an encapsulated organic light-emitting display device, there may be problems where the sealing material 3 does not completely prevent infiltration of moisture. In addition, if the moisture-absorbing material 4 added to relieve the filtration of moisture, should be subject to a sintering procedure, the organic light-emitting diode may be exposed to moisture due to out-gassing induced during the sintering procedure, which may also result in a reduced adhesive force between the sealing material 3 and the substrates.

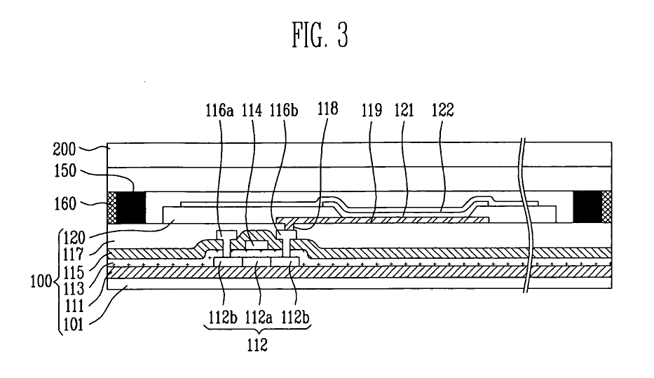

FIG. 2 is a simple plane view showing an organic light-emitting display device according to an embodiment of the present invention; and FIG. 3 is a cross-sectional view taken along a line A-A′ of FIG. 2. Referring to figures, the organic light-emitting display device includes a substrate 100, an encapsulation substrate 200 and frits 150 and 160. For convenience of the description, the substrate 100 means a substrate including an organic light-emitting diode, and deposition substrate 101 means a substrate that becomes a base in which the organic light-emitting diode is formed in an upper portion thereof. Accordingly, the substrate 100 and the deposition substrate 101 will be described separately.

The substrate 100 is a plate including an organic light-emitting diode, and includes a pixel region 100a in which at least one organic light-emitting diode is formed, and a non-pixel region 100b surrounding the pixel region 100a. The organic light-emitting diode comprises a first electrode 119, an organic layer 121 and a second electrode 122. Hereinafter, the pixel region 100a refers to a region for displaying a predetermined image using the light emitted from an organic light-emitting diode, and the non-pixel region 100b refers to the entire substrate except for the pixel region 100a.

The pixel region 100a includes a plurality of scan lines (S1 to Sn) arranged in a horizontal direction, and a plurality of data lines (D1 to Dm) arranged in a vertical direction, and a plurality of pixels electrically connected to the scan lines (S1 to Sn) and the data lines (D1 to Dm). The pixels receive signals over the data lines (D1 to Dm) and the scan lines (S1 to Sn) from a driver integrated circuit. The driver integrated circuit is configured to drive an organic light-emitting display array comprising a plurality of organic light emitting pixels.

In the embodiment shown in FIG. 2, the driver integrated circuit includes a data driving unit 170 and scan driving units 180, 180′. The data driving unit 170 is electrically connected to the data lines (D1 to Dm) while the scan driving units 180 and 180′ are electrically connected to the scan lines (S1 to Sn). The scan driving units 180 and 180′ and the scan lines (S1 to Sn) are shown to be entirely contained in the pixel region 100a. However, the scan driving units 180 and 180′ may be located in the non-pixel region 100b and the scan lines (S1 to Sn) may be partially located in the pixel region 100a and partially in the non-pixel region 100b. Similarly, the data driving unit 170, shown to be located in the non-pixel region 100b, could be located in the pixel region 100a along with the electrically connected data lines (D1 to Dm).

In the embodiment shown in FIG. 2, each of the organic light-emitting pixels in the array is driven in an active matrix method. An example configuration of an organic light emitting pixel contained in the matrix array of FIG. 3 will now be described in brief.

Referring to FIG. 3, a buffer layer 111 is formed on a base substrate 101. The buffer layer 111 may be formed of insulating materials such as silicon oxide (SiO₂) or silicon nitride (SiNx). The buffer layer 111 prevents the substrate 100 from being damaged by factors such as heat from the outside, etc.

On at least one region of the buffer layer 111 is formed a semiconductor layer 112 including an active layer 112a and an ohmic contact layer 112b. On the semiconductor layer 112 and the buffer layer 111 is formed a gate insulating layer 113, and on one region of the gate insulating layer 113 is formed a gate electrode 114 having a size compatible with a width of the active layer 112a.

An interlayer insulating layer 115 is formed on the gate insulating layer 113 and over the gate electrode 114. Via holes are formed in the interlayer insulating layer 115 and the gate insulating layer 113 to expose portions of the ohmic contact layer 112b. Source and drain electrodes 116a and 116b are then formed in the via holes of the interlayer insulating layer 115 and the gate insulating layer 113.

The source and drain electrodes 116a, and 116b are formed so that they are electrically connected to one exposed region of the ohmic contact layer 112b. An overcoat 117 is formed over the interlayer insulating layer 115 and the source and drain electrodes 116a and 116b.

A via hole 118 is formed in the overcoat 117 to expose a portion of the source or drain electrodes 116a or 116b. A first electrode 119 is formed on a region of the overcoat 117, wherein the first electrode 119 is connected with the exposed region of either one of the source or drain electrodes 116a, 116b by means of the via hole 118.

A pixel definition layer 120 is formed over the overcoat 117 and the first electrode 119. An opening is formed in the pixel definition layer 120 to expose at least one region of the first electrode 119.

An organic layer 121 is formed on the opening formed in the pixel definition layer 120, and a second electrode layer 122 is then formed over the organic layer 121 and at least a portion of the pixel definition layer 120. At this time, a passivation layer may be further formed in an upper portion of the second electrode layer 122. It should be noted that various modifications and changes may be made in an active matrix structure or a passive matrix structure of the organic light-emitting diode, and their detailed descriptions are omitted since each of the general structures is known in the art.

An encapsulation substrate 200 is a member for encapsulating at least one pixel region 100a of the substrate in which the organic light-emitting diode is formed, and is preferable formed of transparent materials in the case of top emission or dual emission devices. The encapsulation substrate 200 may be formed of translucent materials in the case of bottom emission devices. Materials of the encapsulation substrate 200 are not limited, but a glass may be preferably used in this embodiment, for example in the case of a top emission display device.

The encapsulation substrate 200 is formed in a plate shape in this embodiment, and encapsulates at least the pixel region 100a in which at least one organic light-emitting diode is formed. In the example shown in FIG. 2, the encapsulated region includes the entire pixel region and part of the non-pixel region not including the data driving unit 170, portions of the associated data lines (D1 to Dm) and a pad unit.

Two frits 150 and 160 are formed between the encapsulation substrate 200 and the substrate 100 in the non-pixel region 100b. The frits are formed to surround the pixel region 100a and are sealed so that the open air is prevented from infiltrating the pixel area 100a. Generally, the frit means a powdery glass material including additives, but also means a glass generally formed by melting a frit in the field of glass. Accordingly, the frit is used to mean both of the glasses in this application.

The frits 150 and 160 may include a glass material, a moisture-absorbing material for absorbing a laser beam, and a filler (e.g., for reducing a thermal expansion coefficient, etc.). In one embodiment, the frits 150 and 160 are applied to faces of the substrate 100 and/or the encapsulation substrate 200 in a form of a frit paste containing an organic binder. The substrate 100 and the encapsulation substrate 200 are coalesced such that the frits 150 and 160 contact each other and both the substrate 100 and the encapsulation substrate 200. The frit paste is then melted and cured to form an interface seal between the encapsulation substrate 200 and the substrate 100. The melting may be accomplished by using a laser beam or an infrared ray to seal the interface between the encapsulation substrate 200 and the substrate 100. Preferably, the frits 150 and 160 are formed to comprise a width of about 0.5 mm to about 1.5 mm (the width of the frit as measured parallel to the substrates, as shown in FIG. 3, in a plane generally perpendicular to a longitudinal axis of the typically elongated frits 150 and 160). If the width is about 0.5 mm or less, the sealing properties may be deficient, possibly resulting in frit seals with poor adhesive properties. If the width exceeds about 1.5 mm, then the quality of the resulting product may be deteriorated since a dead space of the diode becomes larger.

Also, a thickness of each frit 150 or 160 preferably ranges from about 10 μm to about 20 μm (the thickness as measured perpendicular to the substrates in a plane generally perpendicular to a longitudinal axis of the typically elongated frits 150 and 160). If the thickness of the frit(s) 150 and/or 160 exceeds about 20 μm, then the increased energy needed to melt the frits may result in thermal damage to the organic light emitting pixels and/or the various metal lines in the vicinity of the frits. If the thickness of the frit(s) 150 and/or 160 is less than about 10 mm, then the sealing and/or adherence properties of the frits may be deficient.

In one embodiment, the frit 160 is formed on the substrate 100 and the frit 150 is formed on the encapsulation substrate 200, respectively. Preferably, the amount of frit applied to the heat sensitive substrate 100 is less than the amount applied to the encapsulation substrate 200. In the example shown in FIG. 3, the frit 160 is of smaller width (as measured parallel to the substrate as shown in FIG. 3) than the frit 150. Thus, the energy required to sinter the frit 160, on the more heat sensitive substrate 100, is lower than the energy required to sinter the wider frit 150 on the less heat sensitive encapsulation substrate 200. In some embodiments, the thickness of the frit applied to the encapsulation substrate (a thickness measured prior to the coalescing of the substrates, where the thickness is measured perpendicular to the substrates as shown in FIG. 3) 200 is preferably greater than the thickness of the frit applied to the heat sensitive substrate 100.

Meanwhile, configurations and materials of a surface of the substrate 100 with which the frit 150 is in direct contact are not limited. However, the frit is preferably not overlapping with metal wiring as much as possible, except a portion of a metal wiring directly connected with a driver integrated circuit. In this case, the frit may be, for example, directly formed on the deposition substrate composed of a glass. In some embodiments, a reinforcement material such as epoxy resin, for example, may be formed on the outer side of the frit so as to improve brittleness in an organic light-emitting display device (not shown) sealed with the frit.

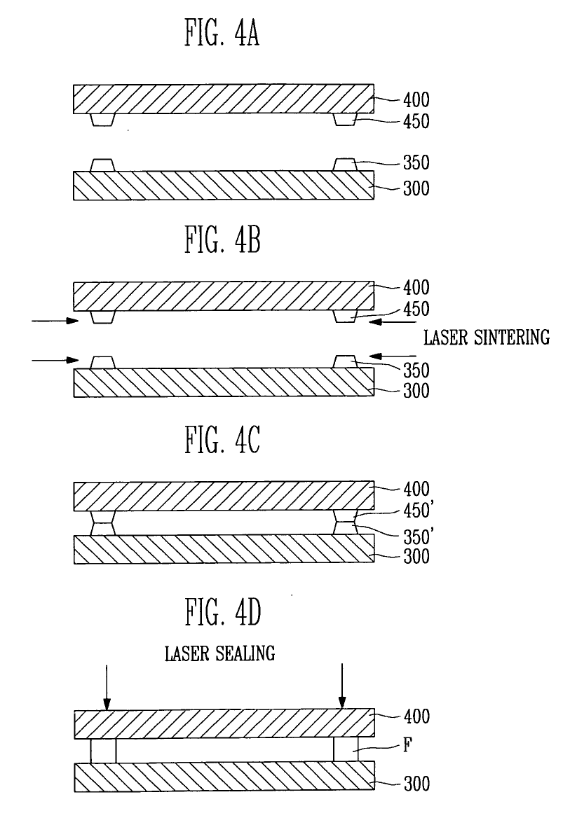

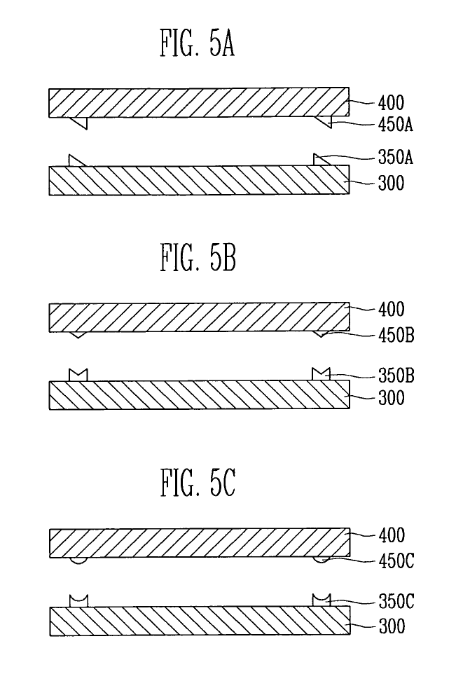

An embodiment of a method for preparing an organic light-emitting display device according to the present invention will be described in detail. FIGS. 4a to 4d are process views showing the process for preparing an organic light-emitting display device in this embodiment.

Firstly, a first frit paste 350 is applied to surround a pixel region in a substrate 300. A second frit paste 450 is applied on an encapsulation substrate 400 to be contacted against the first frit paste 350 when the encapsulation substrate 400 is coalesced against the substrate 300. Application of a frit paste may be conducted using a dispensing or screen method. After the frit pastes 350 and 450 are applied, a surface of each frit paste 350 and 450, where the surface generally faces away from the substrate on which the frit is formed, is preferably made flat (e.g., planarized) to enlarge a contact area of the frits when the frits are contacted. The first and the second frit pastes 350 and 450 preferably include a moisture-absorbing material for absorbing a laser beam or an infrared ray. As described above, the first frit paste 350 (applied to the heat sensitive substrate 300) may comprise a smaller amount of frit paste than the frit past 450 applied to the encapsulation substrate 450. The frit paste 350 may comprise a smaller width than the frit paste 450 (the width as measured parallel to the substrates in FIG. 4A). The frit paste 350 may comprise a smaller thickness than the frit paste 450 (the thickness as measured perpendicular to the substrates in FIG. 4A).

After applying the frit pastes 350 and 450, the first frit 350′ and the second frit 450′ are formed, respectively, by sintering the first and the second frit pastes 350 and 450 and removing an organic binder. Sintering forms a coherent mass from the paste, preferably without melting the paste. Sintering of the second frit paste 450 may be conducted by heating the entire substrate 400, or by topical heating, (e.g., using a laser beam). However, sintering of the frit paste 350 is preferably conducted using topical sintering since the organic light-emitting diodes in the pixel region of the substrate 300 may be damaged if the entire substrate 300 is heated. A power of the laser used for sintering preferably ranges from about 25 W to about 50 W, and a sintering temperature preferably ranges from about 300° C. to about 700° C. (FIG. 4b).

After sintering the frits 350′ and 450′, the substrate 300 and the encapsulation substrate 400 are coalesced such that the first frit 350′ and the second frit 450′ contact each other. The encapsulation substrate 400 is coalesced to encapsulate at least the pixel region of the substrate 300. The term “coalesced” includes a meaning that the substrates are arranged at a closer position so that the first frit 350′ and the second frit 450′ are in contact with each other upon laser irradiation. (FIG. 4c), where contacting can include contact of any surface of the frits 350′ and 450′.

Next, an integrated frit F is formed by irradiating the contacted frits 350′ and 450′ with a laser beam or an infrared ray, so as to attach the substrate 300 and the encapsulation substrate 400 to each other. That is, the contacted frits are irradiated by the laser or the infrared ray, temporally melted and then cured to be attached to each other. At this time, the laser beam or the infrared ray preferably has a wavelength of about 800 nm to about 1,200 nm, and the irradiation of the laser beam or infrared ray may be applied from any direction such as, for example, through the substrate 300 or through the encapsulation substrate 400. The first frit 350′ and the second frit 450′ may be irradiated sequentially or simultaneously and the irradiation may be applied from either direction (through the first substrate 300 and/or through the second substrate 400) or both directions (FIG. 4d). In an embodiment not shown in FIG. 4, the integrated frit seal F includes a middle portion than is narrower in the middle, as measured parallel to the substrates, than at either end attached to the first or second substrates 300 and 400.

After the frit seals have been bonded together, the frit seal my comprise a trace of bonding in a middle portion where the two frits contacted each other prior to and during the melting and attaching of the frits. The trace of bonding may include air bubbles or may be substantially free of air bubbles. The trace of bonding may be a detectable change in the refractive index of the two frits in the middle portion. The trace of bonding may be substantially planar, or a three dimensional geography depending on the shape of the frits prior to being attached. The trace of bonding may be substantially parallel to the surface of the substrates on which the frits were formed. The trace of bonding may comprise a trace of melting and resolidifying of the material of the frit seal.

An embodiment of the method shown in FIG. 4 includes providing a first unfinished product including a first substrate 300 where an array of organic light-emitting pixels is formed on the first substrate 300. The first unfinished product also includes a first frit structure 350 formed over the first substrate and surrounding the array, where the first frit structure 350 includes a first surface generally facing away from the first substrate. The method of this embodiment further includes providing a second unfinished product including a second substrate 400 with a second frit structure 450 formed on the second substrate 400. The second frit structure 450 includes a second surface generally facing away from the second substrate 400. The method further includes arranging the first and second unfinished products such that the first and second surfaces face and contact each other (FIG. 4c), and melting and cooling an interfacial area (e.g., by irradiating with a laser beam as shown in FIG. 4d or with an infrared ray) where the first frit structure 350 and second frit structure 450 contact, so as to bond the first frit structure 350 and second frit structure 450 together, thereby forming an integrated frit seal interposed between the first substrate 300 and the second substrate 400. Preferably, the first frit structure 350 forms a closed loop surrounding the array formed on the first substrate 300 and the second frit structure 450 forms a corresponding closed loop on the second substrate 400.

In one aspect of this embodiment, the first unfinished product includes a plurality of additional arrays of organic light emitting pixels formed on the first substrate. Additionally, a plurality of additional frit structures is formed on the first and second substrates where the additional frit structures are configured to surround the plurality of additional arrays. The additional frit structures are then melted and cooled so as to bond the additional frit structures together to form additional integrated frit seals between the first substrate 300 and the second substrate 400. After forming the plurality of integrated frit seals, the individual arrays can be cut into individual arrays, each including an integrated frit seal surrounding an array of pixels.

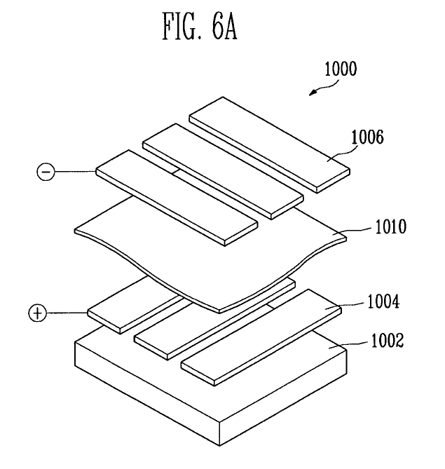

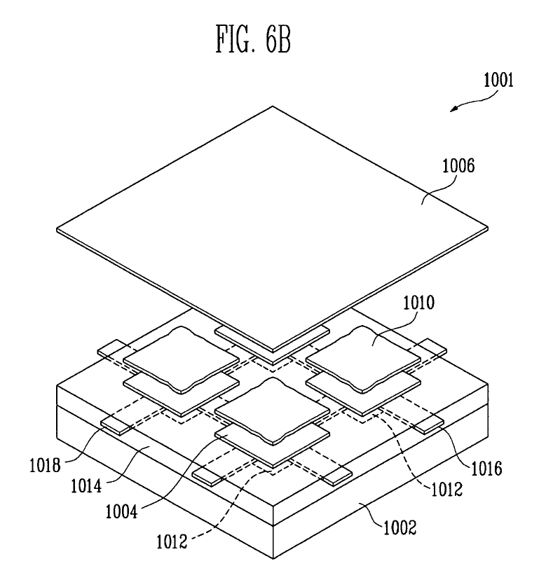

FIGS. 5a to 5c are cross-sectional views showing other embodiments of frit structures that can be formed in the process discussed above in reference to FIGS. 4a to 4d. The various frit structure cross sections shown in FIGS. 5a to 5c are examples of shapes that possess a relatively large amount of contact surface area when they contact each other during the coalescing and irradiating acts of the process shown in FIG. 4. FIG. 5A shows a first frit structure 350A with a triangular cross section and a second frit structure 450A with a reverse triangular cross section. FIG. 5B shows a first frit structure 350B with a five-sided cross section shaped to coalesce with a second frit structure 450B having a triangular cross section. FIG. 5C shows a first frit structure 350C with a four-sided cross section that includes a hollowed out semicircular portion to be coalesced with a second frit structure 450C with a semicircular cross section. Larger contact surface areas can result in increased adhesion forces between the frits when forming the integrated frit seal F as discussed above. Preferably, the amount of frit material applied to the heat sensitive first substrate 300 containing the organic light emitting pixels is less than the amount of material applied to the encapsulating substrate 400.

The present invention has been described in detail with reference to preferred embodiments. However, it would be appreciated that modifications and changes might be made in these embodiments without departing from the principles and spirit of the invention. For example, modifications and changes may be easily made in a relative height of each frit, limitation of materials, etc.

Although a few embodiments of the present invention have been shown and described, it would be appreciated by those skilled in the art that changes might be made in this embodiment without departing from the principles and spirit of the present invention, the scope of which is defined in the claims and their equivalents.

What is claimed is:

1. A method of manufacturing an organic light-emitting display device, the method comprising:
providing a first unfinished product comprising a first substrate and an array of organic light-emitting pixels formed over the first substrate, the first unfinished product further comprising a first frit structure formed over the first substrate and surrounding the array, the first frit structure comprising a first surface generally facing away from the first substrate;
providing a second unfinished product comprising a second substrate and a second frit structure formed over the second substrate, the second frit structure comprising a second surface generally facing away from the second substrate;
arranging the first and second unfinished products such that the first and second surfaces face and contact each other; and
melting and solidifying at least part of the first and second frit structures where the first and second frit structures contact so as to bond the first and second frit structures together, thereby forming an integrated frit seal interposed between the first and second substrate.

2. The method of claim 1, wherein the first frit structure forms a closed loop surrounding the array, and wherein the second frit structure forms a corresponding closed loop over the second substrate.

3. The method of claim 1, wherein the first and second surfaces are shaped complementary so as to substantially fit with each other when the first and second unfinished products are arranged.

4. The method of claim 1, wherein the integrated frit is substantially free of bubbles along where the first and second surfaces contact.

5. The method of claim 1, wherein providing the first unfinished product comprises:
providing the first substrate and the array formed over the first substrate,
forming a structure with a frit material; and
at least partially curing the structure of the frit material, thereby forming the first frit structure.

6. The method of claim 1, wherein the first unfinished product further comprises a plurality of additional arrays of organic light emitting pixels formed over the first substrate and a plurality of additional frit structures formed over the first substrate, each additional frit structure comprising a surface facing away from the first substrate;
wherein the second unfinished product further comprises a plurality of additional frit structures formed over the second substrate, each additional frit structure of the second unfinished product comprising a surface facing away from the second substrate;
wherein upon arranging the first and second unfinished products, the surface of one of the additional frit structures of the first unfinished product contacts the surface of one of the additional frit structures of the second unfinished product; and
wherein the method further comprises melting and solidifying at least part of the two additional frit structures where the two additional frit structures contact so as to bond the two additional frit structures together, thereby forming an additional integrated frit seal interposed between the first and second substrate.

7. The method of claim 6, wherein each of the additional integrated frit seals surrounds one of the additional arrays.

8. The method of claim 6, further comprising cutting the resulting product of claim 6 into two or more pieces, wherein one of the pieces comprises the integrated frit and the array interposed between the first and second substrate.

9. The method of claim 1, wherein one or both of the frit structures comprises one or more materials selected from the group consisting of magnesium oxide (MgO), calcium oxide (CaO), barium oxide (BaO), lithium oxide (Li2O), sodium oxide (Na2O), potassium oxide (K2O), boron oxide (B2O3), vanadium oxide (V2O5), zinc oxide (ZnO), tellurium oxide (TeO2), aluminum oxide (Al2O3), silicon dioxide (SiO2), lead oxide (PbO), tin oxide (SnO), phosphorous oxide (P2O5), ruthenium oxide (Ru2O), rubidium oxide (Rb2O), rhodium oxide (Rh2O), ferrite oxide (Fe2O3), copper oxide (CuO), titanium oxide (TiO2), tungsten oxide (WO3), bismuth oxide (Bi2O3), antimony oxide (Sb2O3), lead-borate glass, tin-phosphate glass, vanadate glass, and borosilicate.

10. A method of manufacturing an organic light-emitting display device comprising a first substrate, an array of organic light-emitting pixels, and a second substrate for encapsulating at least a pixel region of the first substrate, the method comprising:
applying a first frit paste to surround a pixel region in the first substrate;
applying a second frit paste to the second substrate;
sintering the first and the second frit pastes to form a first frit and a second frit, respectively;
arranging the first substrate and the second substrate to contact the first frit and the second frit to each other; and
applying a laser beam to the first frit and the second frit, thereby integrating the first and second frits.

11. The method of claim 10, wherein applying a laser beam provide heat to at least part of the first and second frits.

12. The method of claim 10, wherein the applied first frit paste has a smaller thickness than that of the applied second frit paste, the thickness as measured perpendicular to a surface of the substrate on which the frit is formed.

13. The method of claim 10, wherein the applied first frit paste has a smaller width than that of the applied second frit paste, the width as measured parallel to a surface of the substrate on which the frit is formed.

14. The method of claim 10, wherein the first frit paste comprises a first surface generally facing away from the first substrate, and the second frit paste comprises a second surface generally facing away from the second substrate, and wherein the method further comprises shaping the first and second surfaces complementary to each other.

15. The method of claim 14, wherein shaping the first and second surfaces comprises substantially planarizing the first and second surfaces.
